(19) United States
(12) Patent Application Publication
(10) Pub. No.: US 2024/0188253 A1
(43) Pub. Date: Jun. 6, 2024

(54) COOLING DEVICE FOR SEMICONDUCTOR DEVICE

(71) Applicant: Kioxia Corporation, Tokyo (JP)

(72) Inventors: Tomoya SANUKI, Yokkaichi (JP); Yasuhito YOSHIMIZU, Kawasaki (JP); Yusuke HIGASHI, Leuven (BE); Hideko MUKAIDA, Taito (JP)

(73) Assignee: Kioxia Corporation, Tokyo (JP)

(21) Appl. No.: 18/461,563

(22) Filed: Sep. 6, 2023

(30) Foreign Application Priority Data
Dec. 2, 2022 (JP) 2022-193649

(51) Int. Cl. H05K 7/20

(52) U.S. Cl. CPC H05K 7/20372; H05K 7/20381

(57) ABSTRACT

A semiconductor device according to an embodiment includes: a chamber including an internal structure capable of holding a pressure in the chamber lower than atmospheric pressure; one or a plurality of cooling member provided inside of the internal structure of the chamber, the cooling member holding and cooling a semiconductor device; and a heat transfer part exchanging heat with a refrigerator cooling the cooling member.

### CROSS REFERENCE TO RELATED APPLICATIONS

This application claims the benefit of priority to Japanese Patent Application No. 2022-193649, filed on Dec. 2, 2022, the entire contents of which are incorporated herein by reference.

### FIELD

An embodiment of the present disclosure relates to a cooling device for semiconductor device including a mechanism for cooling a semiconductor device.

### BACKGROUND

In recent years, a semiconductor device such as a memory system including a non-volatile memory has been widely used. A solid state drive (SSD) including a NAND flash memory is known as such a semiconductor device.

It is known that when the flash memory described above is operated at a low temperature, data retention is improved, and characteristic dispersion of a memory cell transistor is reduced, thereby improving a performance of the memory. As a result, it is possible for one memory cell to hold information of a plurality of bits by low-temperature operation. In addition to the flash memory, memory devices such as SRAM (Static Random Access Memory), DRAM (Dynamic Random Access Memory), and MRAM (Magnetoresistive Random Access Memory), or logic devices such as CPU (Central Processing Unit) and GPU (Graphics Processing Unit) have been found to be cooled and operated at low temperatures to improve a performance of the device.

### BRIEF DESCRIPTION OF DRAWINGS

FIG. 1 is a perspective view showing a configuration of a cooling device for semiconductor device according to an embodiment.

FIG. 2 is a top view showing a configuration of a cooling device for semiconductor device according to an embodiment.

FIG. 3 is a cross-sectional view showing a configuration of a cooling device for semiconductor device according to an embodiment.

FIG. 4 is a cross-sectional view showing a method of attaching and detaching a semiconductor device in a cooling device for semiconductor device according to an embodiment.

FIG. 5 is a flowchart of temperature control of a cooling member in a cooling device for semiconductor device according to an embodiment.

FIG. 6 is a diagram showing a configuration of a cooling member in a cooling device for semiconductor device according to an embodiment.

FIG. 7 is a cross-sectional view showing a configuration of a cooling device for semiconductor device according to an embodiment.

FIG. 8 is a cross-sectional view showing an operation of a chamber in a cooling device for semiconductor device according to an embodiment.

FIG. 9 is a cross-sectional view showing an operation of a chamber in a cooling device for semiconductor device according to an embodiment.

FIG. 10 is a cross-sectional view showing a configuration of a cooling device for semiconductor device according to an embodiment.

FIG. 11 is a block diagram showing a configuration of a memory system according to an embodiment.

### DESCRIPTION OF EMBODIMENTS

A cooling device for semiconductor device according to the present embodiment can improve a performance of a semiconductor device such as a memory device or a logic device.

A cooling device for semiconductor device according to an embodiment of the present invention includes: a chamber including an internal structure capable of holding a pressure in the chamber lower than atmospheric pressure; one or a plurality of cooling member provided inside of the internal structure of the chamber, the cooling member holding and cooling a semiconductor device; and a heat transfer part exchanging heat with a refrigerator cooling the cooling member.

Hereinafter, a cooling device for semiconductor device according to an embodiment will be specifically described with reference to the drawings. In the following description, components having substantially the same functions and configurations are denoted by the same reference symbols, and duplicate description may be omitted. Each of the embodiments described below exemplifies an apparatus and a method for embodying the technical idea of this embodiment. The technical idea of the embodiment is not limited to the following materials, shapes, structures, arrangements, and the like of the constituent elements. The technical idea of the embodiment may be added with various modifications with respect to the claims.

### 1. First Embodiment

### [1-1. Configuration of Cooling Device for Semiconductor Device 100]

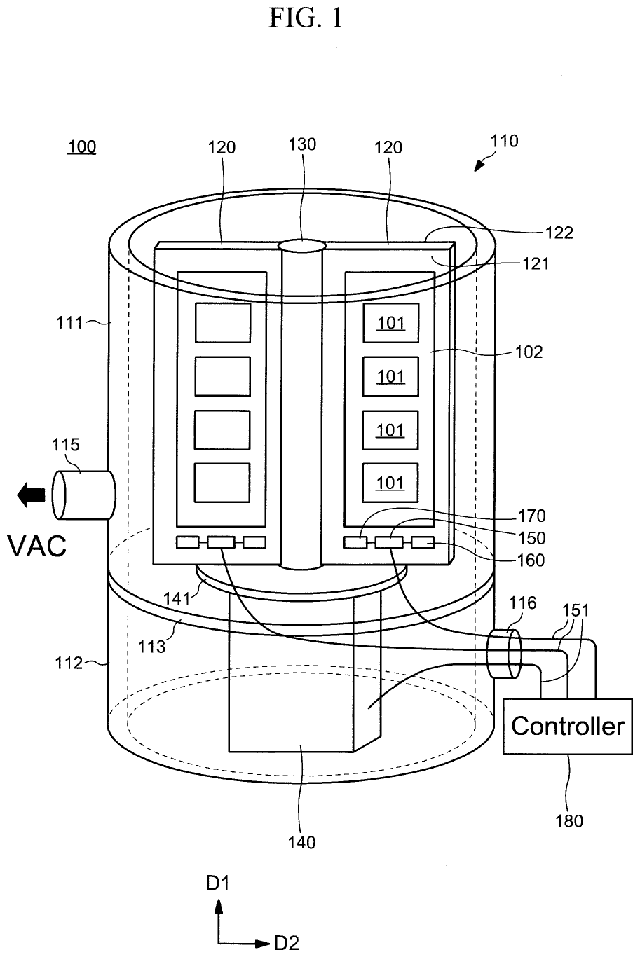

A cooling device for semiconductor device 100 according to a first embodiment will be described with reference to FIG. 1 to FIG. 4. FIG. 1 is a perspective view showing a configuration of a cooling device for semiconductor device according to an embodiment. As shown in FIG. 1, the cooling device for semiconductor device 100 includes a chamber 110, a cooling member 120, a heat transfer part 130, a refrigerator 140, and a controller 180.

The chamber 110 is cylindrical. The chamber 110 includes a first chamber 111 and a second chamber 112. The first chamber 111 and the second chamber 112 arranged adjacent to each other in an axis direction (D1) of a cylindrical shape of the chamber 110. A partition part 113 is arranged between the first chamber 111 and the second chamber 112. The partition part 113 separates an internal space of the first chamber 111 from an internal space of the second chamber 112. That is, a pressure inside the first chamber 111 can be adjusted to a pressure different from a pressure inside the second chamber 112.

Heights of the first chamber 111 and the second chamber 112 in the first embodiment are 20 cm or more and 100 cm or less. Diameters (distances between opposing inner walls) of the first chamber 111 and the second chamber 112 in the first embodiment are 20 cm or more and equal to or 100 cm or less.

The chamber 110 includes a first flange 115 and a second flange 116. The first flange 115 is arranged in the first chamber 111. The second flange 116 is arranged in the second chamber 112. However, the first flange 115 may be arranged in the second chamber 112. The second flange 116 may be arranged in the first chamber 111. The first flange 115 is connected to a vacuum pump (VAC) arranged outside the chamber 110. The first flange 115 is arranged with the vacuum valve. The pressure inside the first chamber 111 is controlled by the vacuum valve. The pressure inside the first chamber 111 can be maintained at a pressure lower than atmospheric pressure (reduced-pressure atmosphere) by the vacuum pump. The second flange 116 is a flange through which a lead wiring 151 to be described later passes. The second flange 116 has a heat insulating function and is configured to thermally insulate the inside and the outside of the second chamber 112.

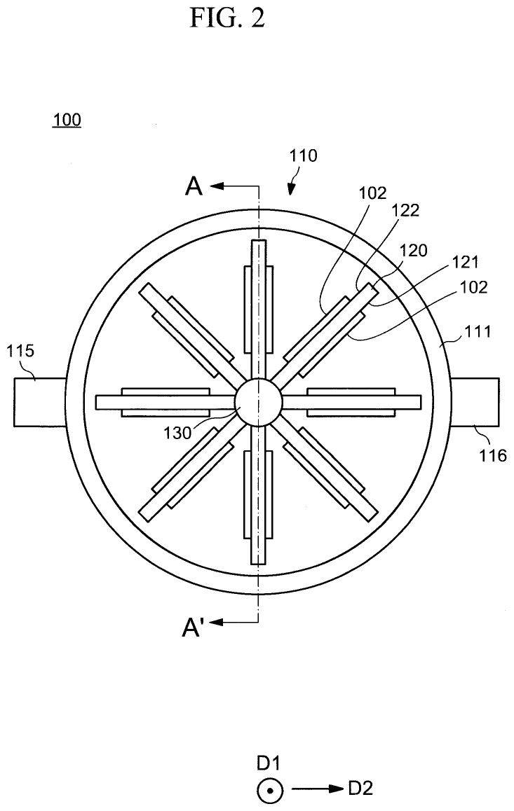

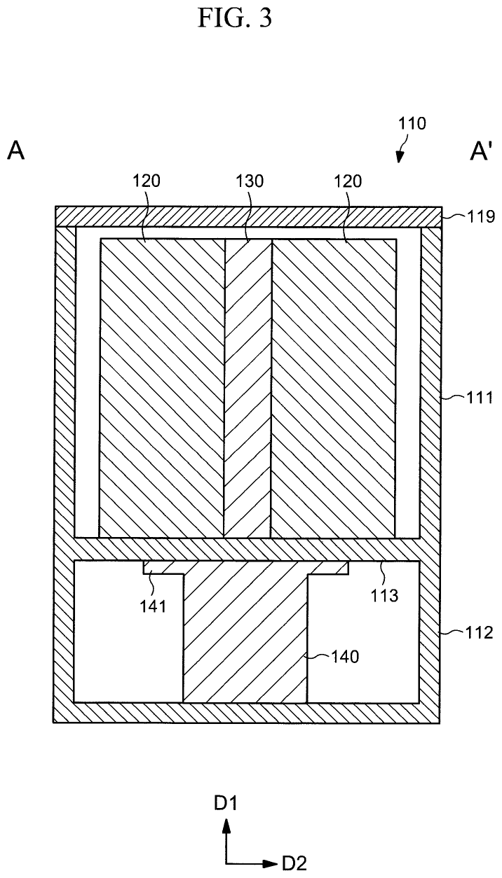

In an upper portion of the first chamber 111, a lid 119 (see FIG. 3) that seals an inside of the first chamber 111 is arranged. However, in FIG. 1 and FIG. 2, the lid 119 is omitted for convenience of explanation.

In the present embodiment, the configuration in which the shape of the chamber 110 is cylindrical is exemplified, but the configuration is not limited to this configuration. For example, the chamber 110 may be shaped as a polygonal prism, polygonal pyramid, or spherical shape. In the present embodiment, the configuration in which the first chamber 111 is connected to the vacuum pump has been exemplified, but the configuration is not limited to this configuration. If the inside of the first chamber 111 can be controlled to be under the reduced-pressure atmosphere, the first chamber 111 may not be connected to the vacuum pump. For example, the chamber 110 may be arranged under the reduced-pressure atmosphere, the cooling member 120 and the heat transfer part 130 may be arranged in the first chamber 111 in this state, and the first chamber 111 may be sealed, whereby the inside of the first chamber 111 may be controlled to be under the reduced-pressure atmosphere. The vacuum pump may be connected to the second chamber 112 instead of the first chamber 111. The vacuum pump may be connected to both the first chamber 111 and the second chamber 112. The partition part 113 may not separate the internal space of the first chamber 111 from the internal space of the second chamber 112. That is, the insides of both the first chamber 111 and the second chamber 112 may be controlled to be under the reduced-pressure atmosphere by the vacuum pump connected to the first chamber 111 or the second chamber 112.

Inside the first chamber 111, the cooling member 120 and the heat transfer part 130 are arranged. The heat transfer part 130 extends upward from the partition part 113 corresponding to a bottom portion of the first chamber 111. In other words, the heat transfer part 130 has a longitudinal length in the axis direction D1 of the cylindrical shape of the first chamber 111. A material of the heat transfer part 130 is a material having a high thermal conductivity, for example, copper (Cu) or aluminum (Al). As the material of the heat transfer part 130, a material having a thermal conductivity of 100 W/mK or more can be used. A shape of the heat transfer part 130 is cylindrical. A diameter of the cylinder is 2 cm or more. In other words, a width of the heat transfer part 130 in the direction (D2) perpendicular to the axis direction (D1) of the cylindrical shape of the first chamber 111 is 2 cm or more. As described above, copper or aluminum is used as the heat transfer part 130, and the diameter or width of the heat transfer part 130 is 2 cm or more, so that a semiconductor device 101 can be sufficiently cooled. For example, in the case where the heights of the first chamber 111 and the second chamber 112 are 20 cm or more and 100 cm or less, and the diameters of the first chamber 111 and the second chamber 112 are 20 cm or more and 100 cm or less, as described above, copper or aluminum is used as the heat transfer part 130, and the diameter or the width of the heat transfer part 130 is 2 cm or more, so that cooling efficiency of the semiconductor device 101 can be improved to the respective stages.

The heat transfer part 130 is in contact with the bottom portion of the first chamber 111. The heat transfer part 130 exchanges heat with the refrigerator 140 described later to cool the cooling member 120. In the present embodiment, the heat transfer part 130 is fixed to the bottom portion of the first chamber 111. However, the configuration is not limited to this configuration, and the heat transfer part 130 may be detachable from the first chamber 111.

The cooling member 120 is connected to the heat transfer part 130. A plurality of cooling members 120 are arranged. In FIG. 1, only a part of the cooling members 120 of the plurality of cooling members 120 is shown (see FIG. 2). A material of the cooling member 120 is a material having a high thermal conductivity, for example, copper (Cu) or aluminum (Al). As the material of the cooling member 120, a material having a thermal conductivity of 100 W/mK or more can be used. The cooling member 120 has a plate shape. A plate thickness of the plate is 1 cm or more. One side of the plate-shaped cooling member 120 is in contact with the heat transfer part 130. Specifically, the cooling member 120 has a rectangular shape having a longitudinal length in the axis direction (D1) of the cylindrical shape of the first chamber 111, and a long side of the rectangular shape is in contact with the heat transfer part 130. As described above, copper or aluminum is used as the cooling member 120 and the plate thickness of the cooling member 120 is 1 cm or more, thereby the semiconductor device 101 can be sufficiently cooled. For example, as described above, in the case where the height of each of the first chamber 111 and the second chamber 112 is 20 cm or more and 100 cm or less, and the diameters of each of the first chamber 111 and the second chamber 112 are 20 cm or more and 100 cm or less, as described above, the cooling member 120 is made of the material having the thermal conductivity of 100 W/mK or more and the plate thickness of the cooling member 120 is 1 cm or more, so that the cooling efficiency of the semiconductor device 101 can be improved to the respective stages.

The cooling member 120 is detachable from the heat transfer part 130. For example, a groove or a convex portion extending along the axis direction (D1) of the cylindrical shape may be formed in the heat transfer part 130. The cooling member 120 can be attached to the heat transfer part 130 by sliding the cooling member 120 in the axis direction of the cylindrical shape with respect to the groove or the convex portion. However, the detachable structure of the cooling member 120 is not limited to the structure described above.

The cooling member 120 includes a first main surface 121 and a second main surface 122. The second main surface 122 is a surface opposite to the first main surface 121. Semiconductor devices 101 are arranged on the first main surface 121 and the second main surface 122. In the present embodiment, a plurality of semiconductor devices 101 are arranged on a print substrate 102. The print substrates 102 are arranged on the first main surface 121 and the second main surface 122. The print substrates 102 are attached to the first main surface 121 and the second main surface 122 of the cooling member 120 by grease, pins, or screws. That is, the cooling member 120 holds the semiconductor devices 101. The number of the print substrates 102 arranged on the first main surface 121 of the cooling member 120 and the number of the semiconductor devices 101 arranged on the print substrate 102 are not limited to the example in FIG. 1.

The cooling member 120 is arranged with a connector 150, a thermometer 160, and a heater 170. The connector 150, the thermometer 160, and the heater 170 are arranged closer to the refrigerator 140 than the semiconductor device 101. The connector 150 is electrically connected to a plurality of semiconductor devices 101 arranged on the print substrate 102. The connector 150, the thermometer 160, and the heater 170 are connected to the wiring 151, and are connected to the controller 180 via the wiring 151. A power supply and a driving signal are input from the controller 180 to the semiconductor device 101 via the connector 150. The thermometer 160 measures temperature of the cooling member 120 and transmits information about the measured temperature to the controller 180 via the connector 150 and the wiring 151. The heater 170 increases the temperature of the cooling member 120 in response to a signal from the controller 180 to prevent the cooling member 120 from being supercooled. The heater 170 is connected to the controller 180 via the connector 150 and the wiring 151.

The thermometer 160 may be arranged farther from the refrigerator 140 than the semiconductor device 101. The thermometer 160 may be arranged in the heat transfer part 130 or may be arranged in both the cooling member 120 and the heat transfer part 130. The thermometer 160 may be arranged at a plurality of positions of the cooling member 120. The heater 170 may be arranged in the heat transfer part 130 or may be arranged in both the cooling member 120 and the heat transfer part 130.

A wired LAN or an optical interconnect may be used as the wiring 151. In the case where the optical interconnect is used, the inside and an outside of the second chamber 112 are connected via an optical fiber capable of transmitting light instead of the wiring 151.

The refrigerator 140 or a part of the refrigerator 140 is arranged inside the second chamber 112. The part of the refrigerator 140 being arranged inside the second chamber 112 is, for example, a configuration in which a cooling member of the refrigerator 140 is arranged inside the second chamber 112, and a power supply portion of the refrigerator 140 is arranged outside the second chamber 112. A top board 141 is arranged at an upper portion of the refrigerator 140. The top board 141 is in contact with a ceiling portion of the second chamber 112, that is, the partition part 113. The refrigerator 140 is connected to the controller 180 via the wiring 151. The refrigerator 140 is a refrigerator that cools by circulating helium-4 (He-4), for example. That is, the refrigerator 140 can be cooled by electric power without the need to use a refrigerant such as liquid nitrogen. The refrigerator 140 has a power of about 100 W. A power efficiency of the refrigerator 140 is 1/50. A cooling temperature by the refrigerator 140 is variable within a range of, for example, 30 K or more and 100 K or less. A height of the refrigerator 140 is 20 cm or more and 100 cm or less.

FIG. 2 is a top view showing a configuration of a cooling device for semiconductor device according to an embodiment. FIG. 2 shows a state in which the lid 119 (see FIG. 3) is removed as in FIG. 1. As shown in FIG. 2, in the case where the first chamber 111 is viewed in the axis direction (D1) of the cylindrical shape, the plurality of cooling members 120 extend radially toward the inner wall of the first chamber 111 around the heat transfer part 130. The number of cooling members 120 is not limited to the example of FIG. 2. The print substrates 102 are arranged on both the first main surface 121 and the second main surface 122 of the cooling member 120.

FIG. 3 is a cross-sectional view showing a configuration of a cooling device for semiconductor device according to an embodiment. FIG. 3 is a cross-sectional view taken along A-A′ line of FIG. 2. As shown in FIG. 3, the lid 119 is arranged at the upper portion of the first chamber 111. The inside of the first chamber 111 is controlled to be under the reduced-pressure atmosphere by the first chamber 111 being sealed by the lid 119. The cooling member 120 and the heat transfer part 130 are in contact with the partition part 113 corresponding to the bottom portion of the first chamber 111. The top board 141 of the refrigerator 140 is in contact with the partition part 113 corresponding to the ceiling portion of the second chamber 112. With this configuration, the cooling member 120 and the heat transfer part 130 can be cooled efficiently. Although FIG. 3 shows a configuration in which the bottom portion of the second chamber 112 is integrated with a side portion of the second chamber 112, the configuration is not limited thereto. For example, the bottom portion may be detachable from the side portion.

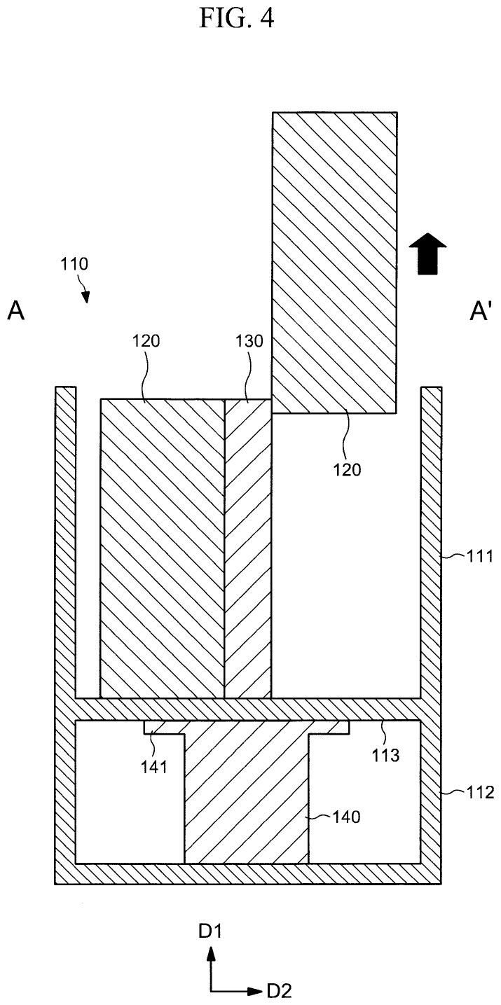

FIG. 4 is a cross-sectional view showing a method of attaching and detaching a semiconductor device in a cooling device for semiconductor device according to an embodiment. As shown in FIG. 4, the cooling member 120 moves upward in a state in which the lid 119 is removed, whereby the cooling member 120 is detached from the heat transfer part 130. Similarly, in a state in which the lid 119 is removed, the cooling member 120 moves downward along the groove or the convex portion formed in the heat transfer part 130 as described above, whereby the cooling member 120 is attached to the heat transfer part 130.

### [1-2. Temperature Control Method of Control Method of Cooling Device for Semiconductor Device 100]

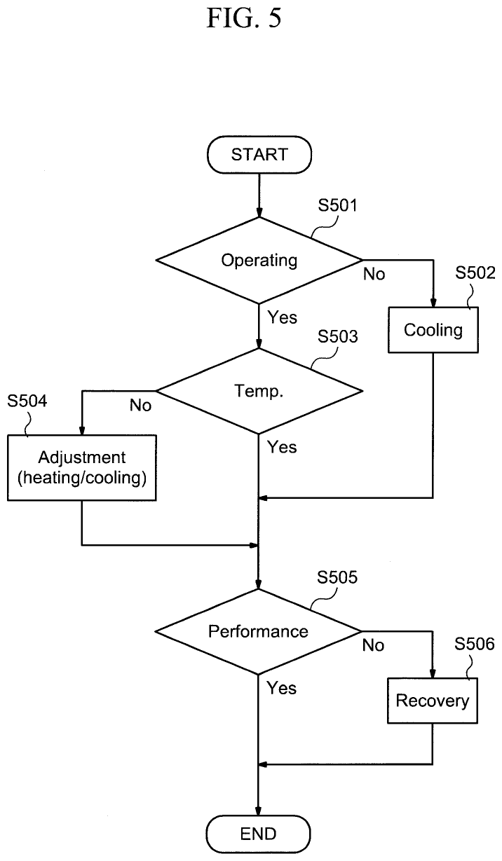

A temperature control method of the cooling device for semiconductor device 100 according to the first embodiment will be described with reference to FIG. 5. FIG. 5 is a flowchart of the temperature control of the cooling member 120 in a cooling device for semiconductor device according to an embodiment. The temperature control shown in the flowchart below is executed by the controller 180.

The temperature control of the cooling member will be described with reference to FIG. 5. First, the pressure inside the first chamber 111 is reduced to a pressure lower than the atmospheric pressure (reduced-pressure atmosphere) by the vacuum pump. After the decompression, the pressure in the first chamber 111 is maintained at the pressure lower than the atmospheric pressure (reduced-pressure atmosphere). In the state where the pressure in the first chamber 111 is maintained at the pressure lower than the atmospheric pressure (reduced-pressure atmosphere), the controller 180 determines an operation state of the semiconductor device 101 (step S501; Operating). In the case where the semiconductor device 101 is in a rest period that does not operate for a predetermined period or longer (“No” in S501), the controller 180 continues to operate the refrigerator 140 and cools the semiconductor device 101 to a resting temperature (step S502; Cooling). On the other hand, in the case where the semiconductor device 101 is in operation or in an operation period (“Yes” in S501), the controller 180 determines whether or not a present temperature of the cooling member 120 is appropriate as a driving temperature (step S503; Temp.). The resting temperature is a temperature lower than the driving temperature. The operation period described above means that the semiconductor device 101 is not currently operating, but may be scheduled to operate or may operate. In other words, the controller 180 controls the cooling member 120 to a lower temperature than a temperature in the period which the semiconductor device 101 operates at S502.

For example, in the case where the semiconductor device 101 is a memory system, in S501, the controller 180 determines whether the memory system is at the rest period or the operation period based on a command transmitted from a host or an operation history of the memory system. The driving temperature of the semiconductor device 101 means a temperature of the cooling member 120 in the case where the semiconductor device 101 is in the operation period. The resting temperature of the semiconductor device 101 means a temperature of the cooling member 120 in the case where the semiconductor device 101 is in the rest period. For example, in the case where the semiconductor device 101 is the memory system as described above, the driving temperature is 70 K to 90 K and the resting temperature is about 30 K. In the case where the memory system is in the operation period, the driving temperature described above is applied in order for a memory cell transistor to operate stably with a predetermined performance. On the other hand, in the case where the memory system is in the rest period, the resting temperature described above is applied in order to improve a holding characteristics of the memory cell transistor.

In S503, in the case where the present temperature of the cooling member 120 is not within the appropriate driving temperature (“No” in S503), the controller 180 adjusts the temperature (step S504; Adjustment (heating/cooling). Specifically, in the case where the temperature of the cooling member 120 measured by the thermometer 160 is less than a lower limit in a range of the appropriate driving temperature, the controller 180 controls an operation of at least one of the semiconductor device 101, the refrigerator 140, and the heater 170 so that the temperature of the cooling member 120 increases.

In order to increase the temperature of the cooling member 120, the controller 180 may turn on the heater 170. Alternatively, the controller 180 may lower a cooling capacity in an operation or stop an operation of the refrigerator 140. Alternatively, the controller 180 may drive the semiconductor device 101 to increase the temperature of the cooling member 120. For example, in a case where the semiconductor device 101 operates based on the command received from the host, driving of the semiconductor device 101 in this case is performed on a circuit independent of (other than) an address designated by the command.

In the case where the temperature of the cooling member 120 measured by the thermometer 160 exceeds an upper limit in the range of the appropriate driving temperature, the controller 180 controls the operation of at least one of the semiconductor device 101, the refrigerator 140, and the heater 170 so that the temperature of the cooling member 120 decreases.

In order to decrease the temperature of the cooling member 120, if the heater 170 is in an on state, the controller 180 may set the heater 170 to an off state. Alternatively, if an output of the refrigerator 140 is not the maximum, the controller 180 may increase the output of the refrigerator 140. Alternatively, the controller 180 may suppress an operation of the semiconductor device 101.

On the other hand, in the case where the present temperature of the cooling member 120 is within the range of the appropriate driving temperature (“Yes” in S503), the controller 180 determines whether a current performance of the semiconductor device 101 meets or exceeds a predetermined standard (step S505; Performance). The performance in S505 is evaluated, for example, by checking error rate of a bit in a write operation or a read operation, or a cumulative number of write operations performed per memory cell.

In S505, in the case where the performance of the semiconductor device 101 is lower than the predetermined standard (“No” in S505), the controller 180 performs a recovery process of the semiconductor device 101 (step S506; Recovery). Specifically, the recovery process of the semiconductor device 101 can be performed by returning the pressure inside the first chamber 111 to normal pressure, stopping the cooling of the first chamber 111, opening the first chamber 111, taking out the semiconductor device 101, and heating the semiconductor device 101 at a temperature lower than a melting point of a solder. It is known that a degradation of the performance of the semiconductor device 101 is caused by a degradation of a gate insulating layer included in the semiconductor device 101, and the degradation of the gate insulating layer is repaired by the heat treatment described above. Specifically, the heat treatment is performed at 125° C. for 1 day or more, or at 250° C. for 3 hours or more.

The recovery process described above can also be realized by, for example, the controller 180 turning on the heater 170 without taking out of the first chamber 111. In this case, the controller 180 stops the operation of the refrigerator 140. Alternatively, as the recovery process described above, the controller 180 may generate a notification signal indicating that performance of the semiconductor device 101 generates, related to the degradation of the gate insulating layer of the semiconductor device 101 or the like, and transmit the notification signal to an external device.

When the recovery process in S506 ends, the process flow shown in FIG. 5 ends. Alternatively, in S505, in the case where the performance of the semiconductor device 101 meets or exceeds the predetermined standard (“Yes” in S505), the process flow shown in FIG. 5 ends.

In the exemplary embodiment of FIG. 5, a configuration in which the steps of S501 to S506 are a series of operations is described, but the configuration is not limited to this configuration. For example, only the steps of S501 and S502 may be configured, and steps S503 to S506 may be omitted. Alternatively, only the steps of S503 and S504 may be configured, and the steps of S501, S502, S505 and S506 may be omitted. Alternatively, only the steps of S505 and S506 may be configured, and the steps of S501 to S504 may be omitted. Alternatively, from the configuration of FIG. 5, only the steps of S501 and S502 may be omitted, only the steps of S503 and S504 may be omitted, and only the steps of S505 and S506 may be omitted.

As described above, according to the cooling device for semiconductor device of the present embodiment, the semiconductor device 101 can be driven in a cooled state, and thus the performance of the semiconductor device 101 can be improved. For example, in the case where the semiconductor device 101 is a flash memory, a dispersion in electric properties of the memory cell transistor can be reduced by operating the flash memory while maintaining the temperature of the cooling member 120 in a cryogenic temperature of 77 K. Therefore, one memory cell transistor can hold information of a plurality of bits, for example, information of 7 bits.

### 2. Second Embodiment

A cooling device for semiconductor device according to a second embodiment will be described. A cooling device for semiconductor device 100 according to the second embodiment is different from the cooling device for semiconductor device 100 according to the first embodiment in the configuration of the cooling member 120. The other configurations are the same as those of the first embodiment, and thus description thereof will be omitted.

### [2-1. Configuration of Cooling Member 120]

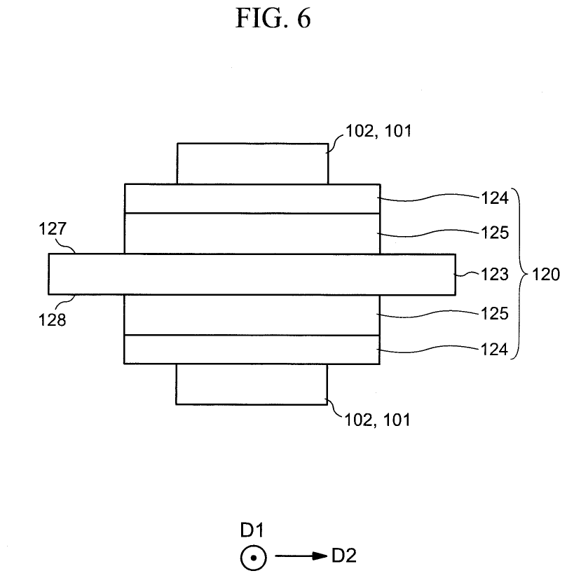

FIG. 6 is a diagram showing a configuration of a cooling member in the cooling device for semiconductor device according to the embodiment. FIG. 6 is a diagram showing a configuration of the cooling member 120 when the cooling device for semiconductor device 100 is viewed from above (opposite to D1) as in FIG. 2. As shown in FIG. 6, the cooling member 120 includes a first plate shape member 123, a second plate shape member 124, and a cold storage member 125. For example, the first plate shaped member 123 is connected to the heat transfer part 130 at an end portion in the direction D2. The second plate shape member 124 holds the semiconductor device 101 via the print substrate 102. The cold storage member 125 is arranged between the first plate shape member 123 and the second plate shape member 124. As shown in FIG. 6, cold storage members 125 and second plate shape members 124 are arranged on both a first surface 127 and a second surface 128 of the first plate shape member 123.

Copper (Cu) or aluminum (Al) is used as the first plate shape member 123 and the second plate shape member 124. Plate thicknesses of the first plate shaped member 123 and the second plate shaped member 124 are 1 cm or more. A material of the first plate shaped member 123 may be the same as or different from a material of the second plate shaped member 124. The plate thickness of the first plate shape member 123 may be the same as or different from the plate thickness of the second plate shape member 124.

As the cold storage member 125, for example, a member having latent heat at a low temperature such as the driving temperature or the resting temperature and capable of storing heat given from outside, or a member having a larger heat capacity than the plate like member 123 and the plate like member 124 is used. Since the cold storage member 125 is arranged between the semiconductor device 101 and the first plate shaped member 123, even if the semiconductor device 101 rapidly generates heat at a speed exceeding cooling capacities of the refrigerator 140, the heat transfer part 130, and the first plate shaped member 123, a speed at which a temperature of the first plate shape member 123 rises is relaxed by the cold storage member 125. Therefore, an increase in temperature of the semiconductor device 101 can be suppressed.

As described above, according to the cooling device for semiconductor device of the present embodiment, even if the semiconductor device 101 rapidly generates heat, it is possible to suppress an increase in temperature of the entire cooling member 120, and thus it is possible to suppress the increase in temperature of the semiconductor device 101.

### 3. Third Embodiment

A cooling device for semiconductor device according to a third embodiment will be described. The cooling device for semiconductor device 100 according to the third embodiment is different from the cooling device for semiconductor device 100 according to the first embodiment in the configuration of the chamber 110. The other configurations are the same as those of the first embodiment, and thus description thereof will be omitted.

### [3-1. Configuration of Cooling Device for Semiconductor Device 100]

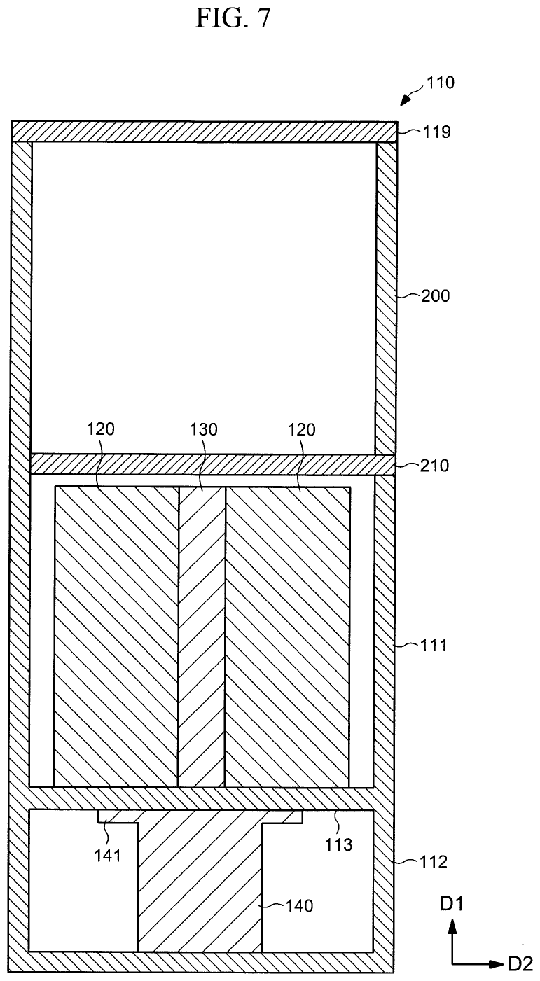

FIG. 7 is a cross-sectional view showing a configuration of a cooling device for semiconductor device according to an embodiment. As shown in FIG. 7, a load lock chamber 200 is arranged so as to be adjacent to and above the first chamber 111. A load lock door 210 is arranged between the first chamber 111 and the load lock chamber 200. The load lock door 210 is an openable door. Opening and closing of the load lock door 210 controls the opening or shielding between the first chamber 111 and the load lock chamber 200. That is, the pressure inside the first chamber 111 and a pressure inside the load lock chamber 200 can be set to different pressures while the load lock door 210 is closed. Although not shown, similar to the first chamber 111, the load lock chamber 200 is arranged with a flange similar to the first flange 115 (see FIG. 1), which is connected to the vacuum pump.

A height of the load lock chamber 200 is 20 cm or more and 100 cm or less, same as a height of the first chamber 111. A diameter of the load lock chamber 200 is 20 cm or more and 100 cm or less, similar to a diameter of the first chamber 111. At an upper portion of the load lock chamber 200, the lid 119 that seals an inside of the load lock chamber 200 is arranged.

### [3-2. Operation of Chamber 110]

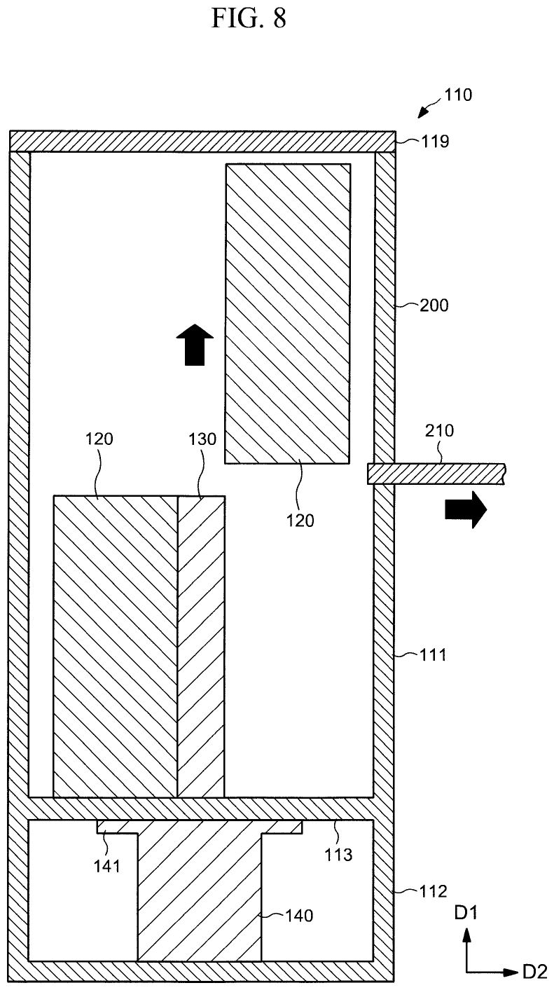

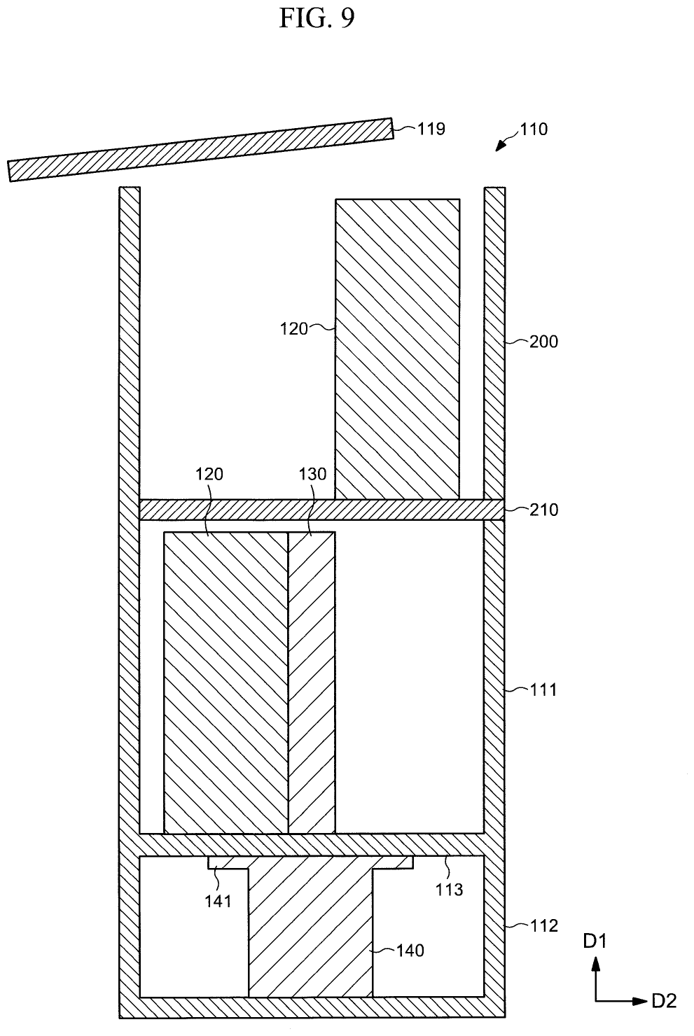

FIG. 8 and FIG. 9 are cross-sectional views showing an operation of a chamber in a cooling device for semiconductor device according to an embodiment. With reference to FIG. 8 and FIG. 9, the operation of the chamber 110 in the case where the cooling member 120 arranged in the first chamber 111 is removed will be described. First, the load lock chamber 200 is evacuated, and the pressure inside the load lock chamber 200 is adjusted to the same level as the pressure inside the first chamber 111.

After evacuation of the load lock chamber 200, as shown in FIG. 8, the load lock door 210 opens and the first chamber 111 and the load lock chamber 200 open. In the case where the load lock door 210 is opened, the cooling member 120 to which the semiconductor device 101 is attached moves from the first chamber 111 to the load lock chamber 200. The movement of the cooling member 120 is performed by a movement mechanism arranged inside the first chamber 111 or the load lock chamber 200.

After the cooling member 120 has moved into the load lock chamber 200, the load lock door 210 closes and the first chamber 111 and the load lock chamber 200 are shielded. In the case where the load lock door 210 is closed, the pressure inside the load lock chamber 200 is adjusted to the atmospheric pressure. After the pressure reaches the atmospheric pressure, as shown in FIG. 9, the lid 119 is removed, and the cooling member 120 to which the semiconductor device 101 is attached is taken out from the load lock chamber 200 to an outside.

As described above, according to the cooling device for semiconductor device of the present embodiment, the cooling member 120 in which the semiconductor device 101 is arranged is attached and detached via the load lock chamber 200. As a result, since the first chamber 111 is not directly exposed under the external atmosphere, it is possible to prevent the inside of the first chamber 111 from being contaminated by the external atmosphere. Further, the semiconductor device can be replaced while the cooling device is in operation.

### 4. Fourth Embodiment

A cooling device for semiconductor device according to a fourth embodiment will be described. Regarding the configuration of the cooling member 120 and the heat transfer part 130, the cooling device for semiconductor device 100 according to the fourth embodiment is different from the cooling device for semiconductor device 100 according to the first embodiment. The other configurations are the same as those of the first embodiment, and thus description thereof will be omitted.

### [4-1. Configuration of Cooling Member 120 and Heat Transfer Section 130]

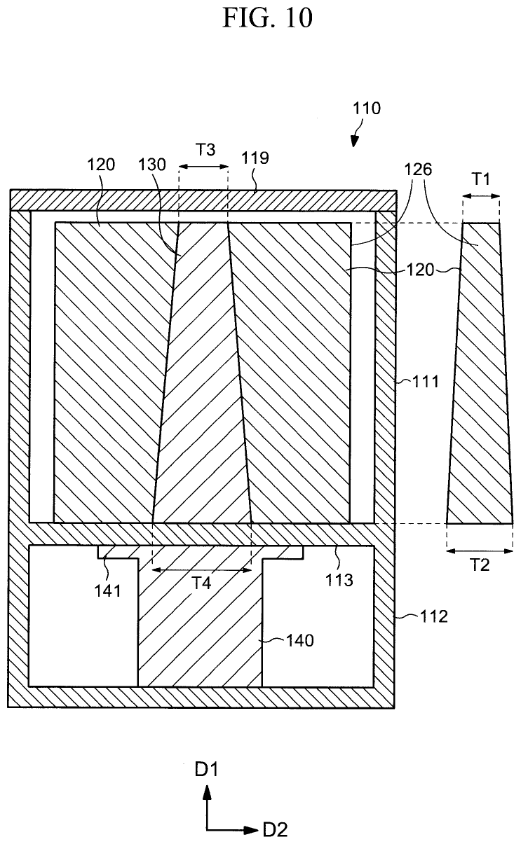

FIG. 10 is a cross-sectional view showing a configuration of a cooling device for semiconductor device according to an embodiment. In FIG. 10, in addition to the cross-sectional view similar to FIG. 3, a shape of a side surface 126 between the first main surface 121 and the second main surface 122 of the cooling member 120 is shown. As shown in FIG. 10, widths (distance between the first main surface 121 and the second main surface 122) of the side surface 126 of the cooling member 120 are different depending on a position of the chamber 110 in the axis direction (D1) of the cylindrical shape. Specifically, a width of the side surface 126 is larger as it is closer to the refrigerator 140 and smaller as it is farther away from the refrigerator 140. That is, a width T1 of the side surface 126 at an upper end of the cooling member 120 is smaller than a width T2 of the side surface 126 at a lower end of the cooling member 120. Similar to the width of the side surface 126 of the cooling member 120, a diameter of the heat transfer part 130 is larger as it is closer to the refrigerator 140 and smaller as it is farther away from the refrigerator 140. That is, a width T3 at an upper end of the heat transfer part 130 is smaller than a width T4 at a lower end of the heat transfer part 130.

The cooling member 120 and the heat transfer part 130 both transfer the heat generated by the semiconductor device 101 to the refrigerator 140. With this configuration, the increase in temperature of the semiconductor device 101 is suppressed. As shown in FIG. 1, since a plurality of semiconductor devices 101 are arranged in the direction D1, a portion of the cooling member 120 and the heat transfer portion 130 closer to the refrigerator 140 transfers more heat generated by the semiconductor device 101. Therefore, in the cooling member 120 and the heat transfer part 130, by increasing a width and a diameter of a portion closer to the refrigerator 140 than a portion farther from the refrigerator 140, it is possible to suppress a stagnation of heat in a vicinity of the refrigerator 140, and it is possible to improve cooling efficiency by the refrigerator 140.

As described above, the cooling device for semiconductor device according to the present embodiment can efficiently cool the semiconductor device 101.

### 5. Fifth Embodiment

A fifth embodiment is a memory system 1 showing an example of the semiconductor device 101 according to the first to fourth embodiments. The memory system according to the fifth embodiment includes, for example, a NAND flash memory as a semiconductor memory device and a memory controller that controls NAND flash memory.

### [5-1. Overall Configuration of Memory System 1]

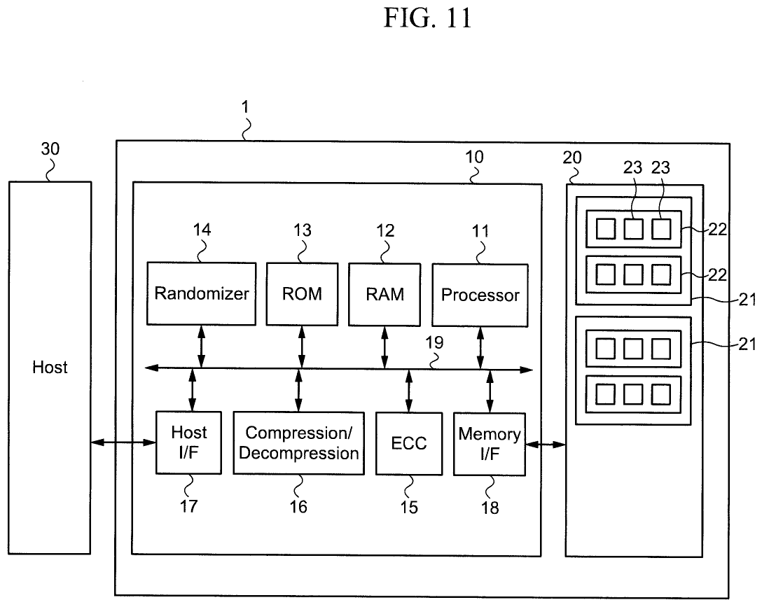

FIG. 11 is a block diagram showing a configuration of a memory system according to an embodiment. As shown in FIG. 11, the memory system 1 includes a memory controller 10 and a non-volatile memory 20 including a plurality of memory cells. The memory system 1 is connectable to a host 30. FIG. 11 shows a state in which the memory system 1 and the host 30 are connected to each other. The host 30 is, for example, an electronic device such as a personal computer or a portable terminal.

The non-volatile memory 20 includes a plurality of memory chips 21. The memory controller 10 controls each of the plurality of memory chips 21. Specifically, the memory controller 10 performs a data write operation, a read operation, and an erase operation on each of the memory chips 21. Each of the plurality of memory chips 21 is connected to the memory controller 10 via a NAND bus.

Each memory chip 21 includes a plurality of dies 22. The die 22 means a wafer unit on which a memory cell is formed. The memory chip 21 is formed by stacking the plurality of dies 22.

Each die 22 is arranged with a plurality of memory blocks 23. The memory block 23 is a unit that can be erased collectively. All memory cell transistors arranged in memory block 23 are connected to the same source line. One unit of the memory block 23 may be referred to as a “physical block”.

The memory block 23 includes a plurality of pages. The write operation and the read operation are performed on a page-by-page basis. The memory cell transistor, which is the smallest unit of a memory device, may be simply referred to as a “memory cell”. A location of a memory cell in a physical block may be referred to as a “physical address.”

The non-volatile memory 20 is a non-volatile memory that stores data in a non-volatile manner. For example, the non-volatile memory 20 is a NAND flash memory (hereinafter, simply referred to as a NAND memory). In the following explanation, the NAND memory is used as the non-volatile memory 20, but a semiconductor memory device other than the NAND memory such as a three-dimensional flash memory, ReRAM (Resistance Random Access Memory), FeRAM (Ferroelectric Random Access Memory) or the like can be used as the non-volatile memory 20. It is not essential that the non-volatile memory 20 be a semiconductor memory device. The present embodiment can be applied to various storage media other than the semiconductor memory device.

The memory system 1 may be a memory card or the like in which the memory controller 10 and the non-volatile memory 20 are configured as a single package, or may be SSD (Solid State Drive) or the like.

The memory controller 10 is a semiconductor-integrated-circuit configured as SoC (System On a Chip), for example. Some or all of the operations of the respective components of the memory controller 10 described below are realized by hardware, but CPU (Central Processing Unit) may be realized by executing firmware.

The memory controller 10 controls a write operation to the non-volatile memory 20 in accordance with a write request (write command) from the host 30, controls a read operation from the non-volatile memory 20 in accordance with a read request (read command) from the host 30, and controls an erase operation to the non-volatile memory 20 in accordance with an erase request (erase command) from the host 30. The memory controller 10 includes a processor 11, RAM 12 (Random Access Memory), ROM 13 (Read Only Memory), a randomizer 14, an ECC circuit 15 (ECC), a compression/decompression circuit 16, a host interface 17 (Host I/F), and a memory interface 18 (Memory I/F). These functional blocks are connected to each other by an internal bus 19.

The processor 11 is a controller that comprehensively controls each functional block of the memory system 1. In the case where a request (command) from the host 30 is received via the host interface 17, the processor 11 performs control according to the command. For example, in response to a write command from the host 30, the processor 11 instructs the memory interface 18 to write data to the non-volatile memory 20. In response to a read command from the host 30, the processor 11 instructs the memory interface 18 to read data from the non-volatile memory 20. In response to an erase command from the host 30, the processor 11 instructs the memory interface 18 to erase data to the non-volatile memory 20.

In the case where a write command is received from the host 30, the processor 11 determines a memory region on the non-volatile memory 20 with respect to data to be written which is temporarily held in the RAM 12. That is, the processor 11 manages a data write destination. A correspondence relationship between a logical address of data received from the host 30 and a physical address indicating a memory region on the non-volatile memory 20 in which the data is stored is stored in an address conversion table. When executing a write operation in response to a write command, the processor 11 can hold a time at which the write operation was performed or a time from a certain reference time in RAM 12.

In the case where a read command is received from the host 30, the processor 11 converts a logical address designated by the read command into a physical address using the address conversion table described above, and instructs the memory interface 18 to perform a read operation from the physical address. When the read operation is performed in response to the read command, the processor 11 can hold a time at which the read operation was performed or a time from a certain reference time in RAM 12.

In the case where an erase command is received from the host 30, the processor 11 converts a logical address specified by the erase command into a physical address using the address conversion table described above, and instructs the memory interface 18 to perform an erase operation according to the physical address. When the erase operation is executed according to the erase command, the processor 11 can hold a time at which the erase operation was performed or a time from a certain reference time in RAM 12.

In NAND memories, a write operation and a read operation are generally performed in units of data called “pages”, and erasing is performed in units of data of the physical blocks described above. In the following description, the “page” means the smallest unit in a write operation. A plurality of memory cells connected to the same word line is referred to as a “memory cell group”. In the case where the memory cell is SLC (Single Level Cell), one page is configured by one memory cell group. In the case where the memory cell is a multi-bit cell such as MLC (Multi Level Cell) in which two pages are formed by one memory cell group, TLC (Triple Level Cell) in which three pages are formed by one memory cell group, or QLC (Quad Level Cell) in which four pages are formed by one memory cell group, one memory cell group corresponds to a plurality of pages. Each memory cell is connected to both a word line and a bit line. Thus, each memory cell can be identified using an address identifying the word line and an address identifying the bit line.

The RAM 12 is used, for example, as a data buffer. The RAM 12 temporarily holds the data which the memory controller 10 received from the host 30 until the data is stored in the non-volatile memory 20. The RAM 12 temporarily holds data read from the non-volatile memory 20 until the data is transmitted to the host 30. For example, general-purpose memories such as SRAM or DRAM can be used as the RAM 12.

The ROM 13 stores various programs, parameters, and the like for operating the memory controller 10. The programs, the parameters, and the like stored in the ROM 13 are read and executed by the processor 11 as needed.

The randomizer 14 includes, for example, a linear feedback shift register or the like, and generates a pseudo-random number which is uniquely determined with respect to an input seed value. The pseudo-random number generated by the randomizer 14 is, for example, a value obtained by calculating an exclusive OR with respect to write data in the processor 11. As a result, the write data to be written to the non-volatile memory 20 is randomized. The randomizer 14 executes a release of the randomization of the data read from the non-volatile memory 20. The release of the randomization is to obtain the original data before the randomization from the randomized data.

The ECC circuit 15 performs an ECC coding (error correction coding) during a write operation and an ECC decoding (error correction decoding) during a read operation based on an instruction from the processor 11. As an encoding method of the ECC circuit 15, an encoding method using, for example, an LDPC (Low-Density Parity-Check) code, a BCH (Bose-Chaudhuri-Hocquenghem) code, or an RS (Reed-Solomon) code can be adopted.

The compression/decompression circuit 16 operates as an encoding unit that compresses data to be written to the non-volatile memory 20. The compression/decompression circuit 16 also operates as a decoding unit that decompresses data read from the non-volatile memory 20.

The host interface 17 executes process according to an interface standard between the host 30 and the host interface 17. The host interface 17 outputs a command received from the host 30, data to be written, and the like to the internal bus 19. The host interface 17 transmits the data read from the non-volatile memory 20 and decompressed by the compression/decompression circuit 16 to the host 30. The host interface 17 transmits, for example, a response from the processor 11 to the host 30.

The memory interface 18 executes a write operation and an erase operation to the non-volatile memory 20 based on the instruction from the processor 11. The memory interface 18 executes the read operation from the non-volatile memory 20 based on the instruction from the processor 11.

### [5-2. Operation of Memory System 1]

In the memory system 1 having the configuration described above, the processor 11 instructs the compression/decompression circuit 16 to compress data when executing the write operation to the non-volatile memory 20. In this case, the processor 11 determines a storage location (storage address) of the write data in the non-volatile memory 20, and instructs the memory interface 18 with the determined storage address. The compression/decompression circuit 16 compresses data on the RAM 12 based on the instruction from the processor 11. The randomizer 14 randomizes the compressed data on the RAM 12 based on the instruction from the processor 11. The ECC circuit 15 further performs the ECC coding the randomized data based on the instruction from the processor 11. The write data thus generated is written to a designated storage address of the non-volatile memory 20 via the memory interface 18.

On the other hand, the processor 11 designates an address on the non-volatile memory 20 at the time of the read operation with respect to the non-volatile memory 20, determines a condition of a read operation of the memory cell according to the designated address, and instructs the memory interface 18 to execute the read operation. The processor 11 instructs the ECC circuit 15 to start ECC decoding, instructs the randomizer 14 to start the release of the randomization, and instructs the compression/decompression circuit 16 to start decompression. In accordance with the instruction from the processor 11, the memory interface 18 executes the read operation with respect to the address of the designated non-volatile memory 20, and inputs the read data obtained by the read operation to the ECC circuit 15. The ECC circuit 15 performs the ECC decoding to the received read data. The randomizer 14 executes the release of the randomization on ECC decoded data. The compression/decompression circuit 16 decompresses the data on which the randomization is released. If the decompression is successful, the processor 11 stores the decompressed original data in the RAM 12. On the other hand, if the ECC decoding or the release of the randomization or decompression fails, the processor 11 notifies the host 30 of a read error, for example.

Although the present disclosure has been described with reference to the drawings, the present disclosure is not limited to the embodiments described above, and can be appropriately modified without departing from the spirit of the present disclosure. For example, based on the cooling device for semiconductor device according to the present embodiment, a cooling device for semiconductor device in which a person skilled in the art appropriately adds, deletes, or changes in design of the constituent elements, is included in the scope of the present disclosure as long as the gist of the disclosure is provided. Furthermore, the embodiments described above can be appropriately combined as long as there are no mutual contradictions, and technical matters common to the embodiments are included in the embodiments without explicit description.

It is to be understood that the present disclosure provides other operational effects that are different from operational effects provided by aspects of the embodiments described above, and those that are obvious from the description of the present specification or those that can be easily predicted by a person skilled in the art.

What is claimed is:

1. A cooling device for semiconductor device comprising:
a chamber including an internal structure capable of holding a pressure in the chamber lower than atmospheric pressure;
one or a plurality of cooling member provided inside of the internal structure of the chamber, the cooling member holding and cooling a semiconductor device; and
a heat transfer part exchanging heat with a refrigerator cooling the cooling member.

2. The cooling device for semiconductor device according to claim 1, wherein internal pressure of the chamber can be reduced to a pressure lower than the atmospheric pressure by a vacuum pump.

3. The cooling device for semiconductor device according to claim 1, wherein
the chamber is a cylindrical shape, and
the heat transfer part has a longitudinal in an axis direction of the cylindrical shape of the chamber.

4. The cooling device for semiconductor device according to claim 3, wherein the cooling member is a plate shape.

5. The cooling device for semiconductor device according to claim 4, wherein thickness of the cooling member is 1 cm or more.

6. The cooling device for semiconductor device according to claim 4, wherein thermal conductivity of the cooling member is 100 W/mK or more.

7. The cooling device for semiconductor device according to claim 4, wherein the cooling member includes copper or aluminum.

8. The cooling device for semiconductor device according to claim 4, wherein the cooling member extends to the axis direction of the cylindrical shape, and extends from the heat transfer part toward an inner wall of the chamber.

9. The cooling device for semiconductor device according to claim 4, wherein
the plurality of cooling members are provided, and
the plurality of cooling members extend radially around the heat transfer part when viewed in the axis direction of the cylindrical shape.

10. The cooling device for semiconductor device according to claim 5, wherein
the heat transfer part is a rod shape having a longitudinal in the axis direction of the cylindrical shape, and
a width of the heat transfer part in a direction perpendicular to the axis direction of the cylindrical shape is 2 cm or more.

11. The cooling device for semiconductor device according to claim 1, wherein
the cooling member includes
a first plate shape member connected to the heat transfer part,
a second plate shape member holding the semiconductor device, and
a cold storage member between the first plate shape member and the second plate shape member.

12. The cooling device for semiconductor device according to claim 1, wherein the cooling member includes a thermometer and a heater.

13. The cooling device for semiconductor device according to claim 12, further comprising a controller connected to the thermometer and the heater,
wherein the controller is configured to turn on the heater in the case where a temperature measured by the thermometer is a predetermined temperature or less.

14. The cooling device for semiconductor device according to claim 12, further comprising a controller,
wherein
the cooling member includes a thermometer connected to the controller, and
the controller is configured to increase a temperature of the cooling member by driving the semiconductor device in the case where a temperature measured by the thermometer is a predetermined temperature or less.

15. The cooling device for semiconductor device according to claim 1, further comprising a controller,
wherein the controller is configured to control the cooling member to lower temperature than a temperature in a period in which the semiconductor device is driven in the case where the semiconductor device has not been driven in a predetermined time or more.

16. The cooling device for semiconductor device according to claim 1, further comprising a controller,
wherein
the cooling member includes a heater connected to the controller,
the controller is configured to heat the semiconductor device by turning on the heater in the case where a performance of the semiconductor device is a predetermined standard or less.

17. The cooling device for semiconductor device according to claim 12, wherein internal pressure of the chamber can be reduced to a pressure lower than the atmospheric pressure by a vacuum pump.

18. The cooling device for semiconductor device according to claim 1, further comprising a controller,
wherein the controller generates a notification signal notifying degradation of a performance of the semiconductor device in the case where the performance of the semiconductor device is a predetermined standard or less.

19. The cooling device for semiconductor device according to claim 1, further comprising a load lock chamber adjacent to the chamber via a door capable of opening and closing,
the semiconductor device moves from the chamber to the load lock chamber in the case where the door is open state, and
the semiconductor device is detached from the load lock chamber to outward in the case where the door is closed.
